(19) United States
(12) Patent Application Publication
(10) Pub. No.: US 2004/0000704 A1
(43) Pub. Date: Jan. 1, 2004

(54) Process for grid array assembly and electronic device made thereby

(76) Inventor: George Tsao, Taoyuan Hsien (TW)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(21) Appl. No.: 10/188,272

(22) Filed: Jul. 1, 2002

(51) Int. Cl. H01L 23/06

(52) U.S. Cl. 257/684

(57) ABSTRACT

A process is provided to modify the conventional process of concurrently spreading solder pastes for both of the SMT components and the BGA components by conducting different novel printing processes for the respective components. The novel printing process of the present invention comprises the steps of: spreading or syringing a paste flux on the soldering pads of the printed circuit board for the BGA components, wherein the paste flux does not contain solder balls or other types of solder; spreading a solder paste on the soldering pads of the printed circuit board for the SMT components; and reflowing the circuit components on the soldering pads of the printed circuit board for the BGA components and the SMT components, respectively.

The present invention further provides an electronic device made by the above printing process.

### BACKGROUND OF THE INVENTION

(A) Field of the Invention

The present invention relates to an improved process for grid array assembly and an electronic device manufactured by the process, and, in particular, to a process of spreading a solder paste on the soldering pads for a surface mounting technology (SMT) component and a paste flux on the soldering pads for a grid array package component, respectively, and an electronic circuit made by the process.

(B) Description of Related Art

In the SMT process, there is a trend that the associated products and components are becoming “lighter, slimmer, shorter, and smaller,” such that the packaging of the SMT components has to be more compact. For this reason, there is a bottleneck of the SMT process. As shown in FIG. 1A, for the conventional SMT process of spreading solder pastes, a stencil 1 and solder paste 2 have the so-called characteristic restriction of 1:1.5 ratio. That is, an opening A of the Stencil 1 has to be in a size about one and a half larger than the thickness B of the stencil 1. If the ratio is not satisfied, the solder paste 2 applied on the stencil 1 is apt to block up the opening A of the stencil 1 such that the solder paste cannot be spread over the circuit board to be printed. This inevitably limits the highly condensation development of the SMT QFP components. Currently, in a conventional process of spreading solder paste, a minimum pin pitch of an SMT IC/QFP component is about 0.4 mm. The application of BGA components in the SMT IC/QFP components can more efficiently utilize the limited space on the printed circuit board. Also owing to the application of BGA components in the SMT IC/QFP components, in which initially, larger grains of solder balls are used and the distance between the solder balls is greater, say at least 0.8 mm, the bottleneck previously existed in the solder paste spreading process has been temporarily improved. However, with the advancement of the technologies, the BGA components will also be made “much lighter, slimmer, shorter, and smaller” according to a process in which either the grains of the solder balls or the pitch between the solder balls is reduced. Even so, the application of the BGA components after reduction still has the same limitation as the conventional SMT IC/QFP components. As shown in FIG. 1B, according to the rules of thumb, upon application of the BGA components, the ratio of the thickness B of the stencil 1 to the opening A of the stencil 1 is about 1:3. That is, the opening A of the stencil 1 has to be three times larger than the thickness of solder paste 2. Otherwise, the same defect of the conventional SMT will be encountered, in which the solder paste 2 applied on the stencil 1 is apt to block up the opening A of the stencil 1 such that the solder paste cannot be spread over the circuit board to be printed. The inventor of the present application expresses that in order to correct such defect, the above-mentioned conventional SMT IC/QFP process of spreading solder paste has to be modified.

The technique of the above-described solder paste spreading process differs from that of the conventional silk screen printing process, such as for printing newspapers in some aspects. One aspect is the silk screen printing is a sort of ink printing, in which the ink is liquid and has no large grains of additives. Therefore, the ink has good permeability so that it can pass through the openings of the silk screen or the stencil, and thus can adhere to the substances to be printed. However, in the process of spreading solder paste for the SMT components, as shown in FIG. 1, the solder paste is composed of plenty of tiny grains of solder balls and flux. The tiny solder balls still have some dimensions such that after spread by the squeegee into the openings of the stencil of the thickness B, the solder balls cannot (smoothly pass through the openings A of the Stencil 1 due to the resultant resistance caused by the phenomenon that the solder balls squeeze into the others, the friction between the solder balls and the inner walls of the openings A, and the stickiness of the solder paste 2. For this reason, the solder paste 2 blocks up the openings A of the Stencil 1 such that it cannot be spread over the circuit board. The greater the thickness of the Stencil is, the larger the resistance will be.

The above defect can be corrected by reducing the thickness B of the stencil 1. However, the reduced thickness B of the Stencil 1 will inevitably result in the insufficient amount of the solder paste spread on the soldering pads for the SMT components. Thus, there exist problems of welding without any solder, insufficient amount of solder paste, and soldering strength. That is the reason why the pin pitch of the conventional SMT IC/QFP component cannot be reduced by decreasing the thickness B of the stencil 1.

### SUMMARY OF THE INVENTION

In order to correct the defects of the conventional technologies, the inventor of the present invention considers that some new printing processes for the BGA components with reduced pitch have to be developed. One process is to modify the conventional process of concurrently printing solder pastes for both of the SMT IC/QFP components and the BGA components by conducting different novel printing processes for respective components. The novel printing processes of the present invention can solve the problems encountered not only by the BGA components but also by the BGA like components. The so-called BGA like components are those components, such as flip chips, whose soldering areas are attached with solder bumps or other materials or metal/alloy by setting up balls or other available methods.

Therefore, one object of the present invention is to provide an improved process for soldering grid array components, which can enhance the robustness and effects of the soldering of the grid array components.

Another object of the present invention is to provide an improved process for soldering grid array components and SMT components. which call enhance the respective reliabilities of the soldering of the grid array components and the SMT components.

Yet another object of the present invention is to provide an electronic device made by the above-mentioned processes.

### BRIEF DESCRIPTION OF THE DRAWINGS

The present invention is described below by way of examples with reference to the accompanying drawings, which will help the interested people better understand the objects, technical contents, characteristics and effectiveness of the present invention, wherein

FIG. 1A is a schematic view of a stencil used in a conventional SMT IC/QFP component;

FIG. 1B is schematic view of a stencil used in a conventional BGA component;

FIG. 1C schematically shows that a solder paste is applied into an opening of a stencil during a solder paste printing process of a conventional SMT IC/QFP component;

FIG. 2 schematically shows how to spread a paste flux over a solder pad of a circuit board for a BGA component according to a first embodiment of the present invention;

FIG. 3A schematically shows how to spread or syringe a paste flux on a solder pad of a circuit board for a BGA component according to a second embodiment of the present invention;

FIG. 3B schematically shows how to spread a solder paste on a solder pad of a circuit board for a SMT component according to the second embodiment of the present invention;

FIG. 3C schematically shows how to reflow the SMT component and BGA component on the respective soldering pads of the circuit board according to the second embodiment of the present invention;

FIG. 4 schematically shows how to press a solder paste on a solder pad of a circuit board for a SMT component according to a third embodiment of the present invention; and

FIG. 5 schematically shows how to syringe a paste flux on a solder pad of a circuit board for a BGA component according to the first and third embodiments of the present invention.

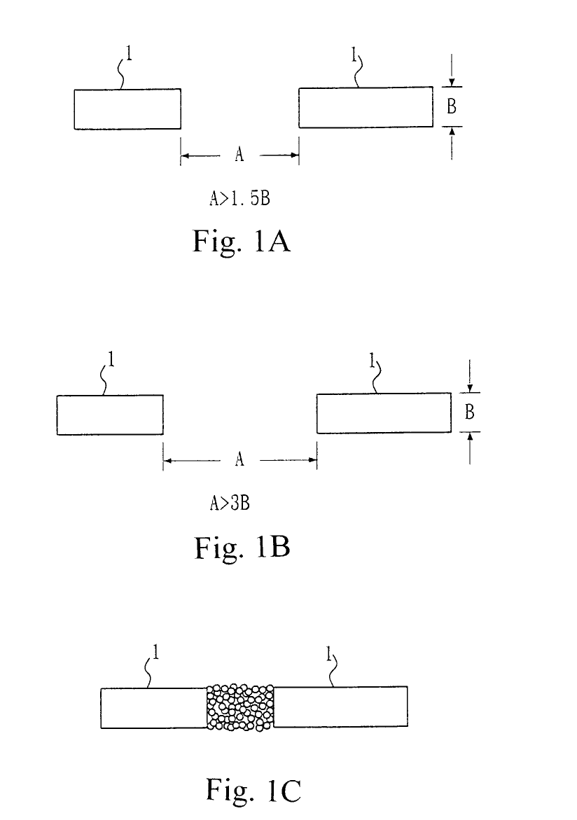

### DETAILED DESCRIPTION OF THE INVENTION

Different embodiments will be explained with reference to the drawings, in which like elements have like reference numerals.

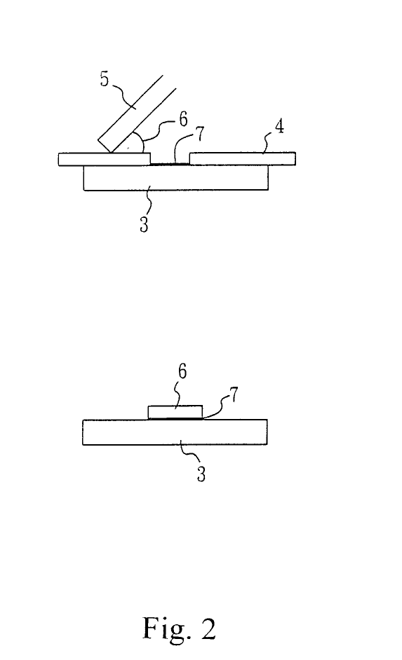

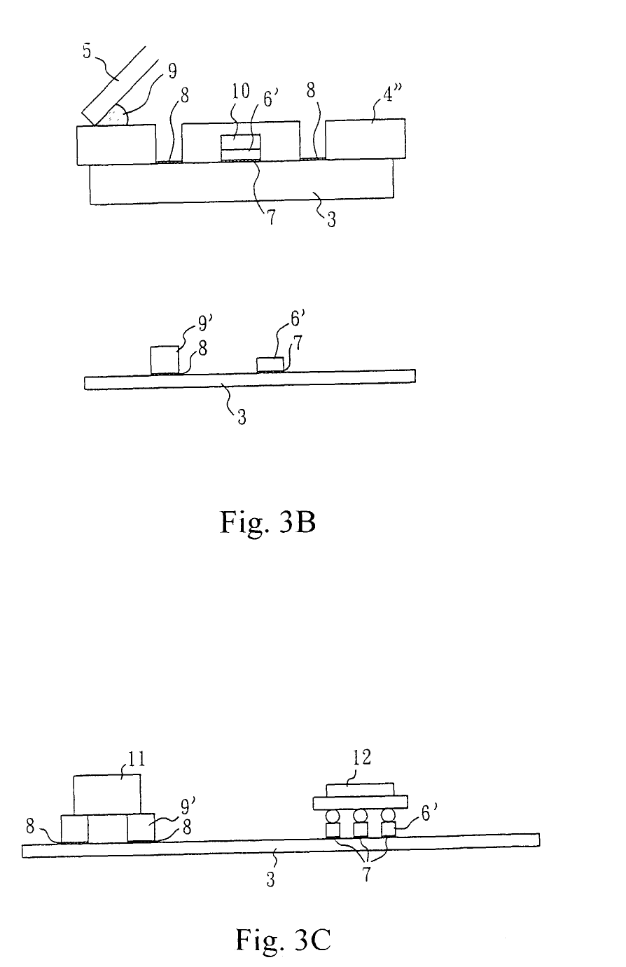

As shown in FIG. 2, according to the first embodiment of the present invention, in the case that mounted on the circuit board 1 are only BGA components or other components having solder bumps (solder balls or other types of solder parts) instead of other SMT components, the conventional solder paste printing process can be modified. First, the process according to the first embodiment of the present invention is to spread by means of squeegee 5 or syringe (see FIG. 4) a paste flux 6, excluding any solder balls, on soldering pads 7 of the circuit board 3 for mounting the BGA components. Next, the BGA like components are positioned on the soldering pads 7 and the subsequent reflow process is conducted. According to the present invention, preferably, the thickness of a paste flux 6′ spread on the circuit board 3 does not exceed 0.3 mm, the length of the surface area of the paste flux 6′ spread on the surface of the circuit board 3 does not exceed 3 mm and the width thereof does not exceed 3 mm. Preferably, the height of the paste flux 6′ syringed on the surface of the circuit board 3 does not exceed 3 mm, the length thereof does not exceed 3 mm, and the width thereof does not exceed 3 mm.

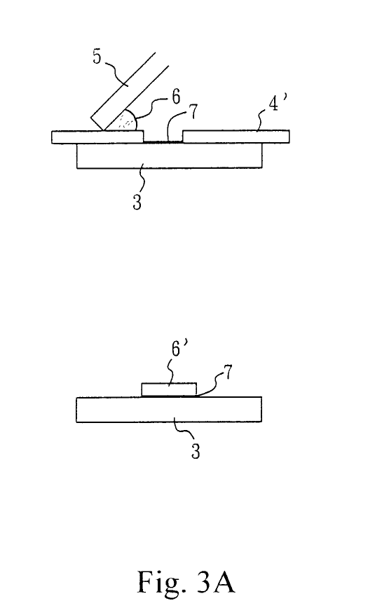

As described above, during the conventional process of spreading solder paste for SMT components, solder pastes are concurrently spread over the soldering pads for the BGA components and the SMT components. According to a second embodiment of the present invention, unlike the conventional process of spreading solder pastes for SMT components, the solder paste spreading is conducted twice as follows. As shown in FIG. 3A, the paste flux 6 excluding any solder balls is spread over the soldering pads 7, on which BGA components are mounted, of a silk screen or a thinner stencil 4′, such as of 0.05 or 0.1 mm. Next, as shown in FIG. 3B, a solder paste 9 is spread over a thicker stencil 4″ whose lower portion are semi-etched for the soldering pads 8 on which other SMT components are mounted. As shown in FIG. 3C, a BGA component 12 and a SMT component 11 are mounted on the soldering pads 7 and the soldering pads 8, respectively and the subsequent reflow process is then conducted. According to the second embodiment of the present invention, the stencil 4″ with semi-etched portion is provided, when the solder paste 9 is spread, for retaining the paste flux 6′ pressed at the first time within a semi-etched opening 10 so as to avoid the interference of the paste flux 6′ spread at the first time with the stencil 4″ when the solder paste 9 is spread.

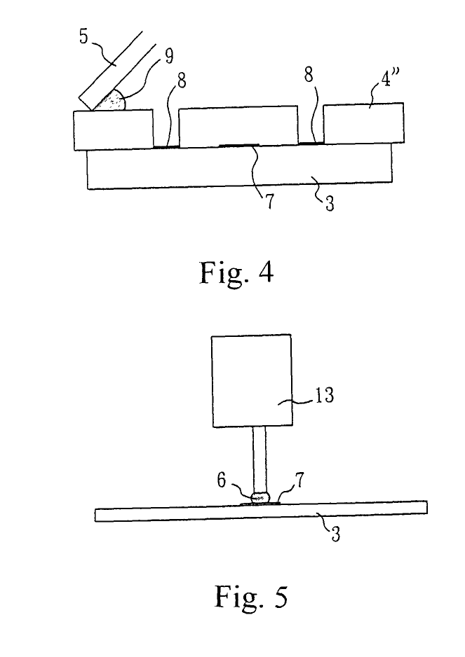

According to a third embodiment of the present invention, as shown in FIG. 4, the conventional process of spreading solder pastes for SMT components is modified. First of all, a process of spreading the solder paste 9 is conducted only with respect to the soldering pads 8 for the conventional SMT component 11 with the exception of the soldering pads 7 for the BGA component 12. Next, referring to FIG. 5, instead of doting the glue during the conventional process of glue doting, the present invention syringes the paste flux 6 by means of a syringe needle 13 the soldering pads 7 for the BGA component or other components having solder bumps (solder balls or other types of solder parts) on the circuit board 3. Then, the components 11 and 12 are mounted on the soldering pads 8 and 7, respectively, for the subsequent reflow process.

Advantages of the novel processes according to the present invention are given as follows:

1. For the BGA component 12, since the BGA component 12 has solder balls installed on its surface, the bonding solder can be provided directly from the installed solder balls. The conventional process of spreading solder paste merely provides the BGA component with the flux contained in the solder paste for further enhancing the soldering effect. Therefore, the process of just spreading or syringing the paste flux 6 according to the present invention will not influence the bonding effect of the BGA component or BGA like component.

2. The permeability of solders through the stencil has been significantly improved since the solder balls are removed from the solder paste 9 and thus the resistance incurred when the grains of the solder balls pass through the openings of the stencil has been reduced. This effectively lessens the restriction of the ratio of the opening A of the stencil 1 to the thickness B thereof. Also due to the fact that the paste flux 6 is spread over the soldering pads for the BGA component 11, the thickness B of the Stencil 1 can become more thinner, and then the opening A thereof can be reduced in its diameter. In this case, a silk screen can replace the conventional stencil during the printing process, and thus the cost of making the stencil can be saved.

3. Similar to the principle of spreading the solder paste through stencil, when syringing the conventional solder paste, because the solder paste contains solder balls and the solder paste is apt to dry and harden, the solder paste would easily block up in the syringe needle 13. However, the syringing of the paste flux according to the present invention will not have such a defect.

4. For larger scale of BGA components or some BGA components packing in some special manner, such as those BGA components whose surfaces are covered by metal masks or large ceramic bodies or high thermal absorptive materials, during the solder paste printing process of the above-mentioned BGA components, the bonding of the solder balls to the soldering areas has to be made through the thermal conduction of the solder pastes. However, since the soldering areas are tiny and the body of the BGA component inevitably absorbs a large amount of thermal energy, the solder paste Is probably not heated enough and thus is not melted completely due to the insufficient absorption of heat. Consequently, the bonding among the solder balls of the BGA component, the solder paste, and the soldering areas of the circuit board is weak. On the contrary, according to the present invention, after the process of printing or syringing the paste flux, the solder balls of the BGA component firmly contact with the soldering areas, and can be thermally conducted quicker than the prior art. The soldering effect is thus enhanced.

5. For the conventional process of spreading solder paste, the solder paste contains the paste flux merely at about 10 percentage of volume, and thus the less amount of paste flux renders the solder paste to easily dry and harden. When the spread solder paste dries and hardens soon, the BGA components are apt to shift in position or even fall down (the dry solder paste is no longer of any stickiness) during the SMT process. To the contrary, due to the greater amount of the paste flux in the paste, the spread or syringed paste flux excluding solder balls will not dry so soon, which facilitates the stabilization of the BGA components on the printed circuit and improves their soldering effects.

The technical contents and features of the present invention have been disclosed in the above embodiments and will not be limited thereto. Persons skilled in the art can possibly modify or change the details in accordance with the present invention to achieve the same effectiveness, without departing from the technologic ideas and spirits of the invention, which are recited in the appended claims.

What is claimed is:

1. A method for mounting a circuit component on a surface of a printed circuit board, wherein the circuit component has a plurality of solder bumps, and the surface of the circuit component has soldering pads corresponding to the plurality of solder bumps, the method comprising the steps of:
(a) overlaying said paste flux on the soldering pads of the printed circuit board, wherein said paste flux does not contain solder balls or other types of solder;
to (b) mounting the circuit component on the soldering pads of the printed circuit board; and
(c) reflowing the circuit component on the soldering pads of the printed circuit board.

2. The method according to claim 1, wherein step (a) is conducted by spreading the paste flux by means of a squeegee.

3 The method according to claim 1, wherein step (a) is conducted by syringing the paste flux by means of a glue gun.

4. The method according to claim 2, wherein the thickness of the paste flux spread on the surface of the printed circuit board does not exceed 0.3 mm.

5. The method according to claim 2, wherein the length of the surface area of the paste flux spread on the surface of the printed circuit board does not exceed 3 mm and the width thereof does not exceed 3 mm.

6. The method according to claim 3, wherein the height of the paste flux syringed on the surface of the printed circuit board does not exceed 3 mm, the length thereof does not exceed 3 mm, and the width thereof does not exceed 3 mm.

7. A method of mounting a first circuit component and a second circuit component on a surface of a printed circuit board, wherein the first circuit component has a plurality of solder bumps, the second circuit component has a plurality of solder pins, and the surface of the circuit component has first soldering pads corresponding to the plurality of solder bumps and second soldering pads corresponding to the plurality of solder pins of the second circuit component, the method comprising the steps of:
(a) overlaying a paste flux on the first soldering pads of the printed circuit board, wherein said paste flux does not contain solder balls or other types of solder;
(b) overlaying a solder paste on the second soldering pads of the printed circuit board by means of a stencil, wherein the surface of the stencil facing the printed circuit board has semi-etched openings corresponding to the first soldering pads of the printed circuit board, and the stencil has through patterns only corresponding to the second soldering pads of the printed circuit board;
(c) mounting the first and second circuit components on the first and second soldering pads of the printed circuit board, respectively; and
(d) reflowing the first and second circuit components on the first and second soldering pads of the printed circuit board.

8. The method according to claim 7, wherein step (a) is conducted by spreading the paste flux on another stencil positioned on the printed circuit board by means of a squeegee, and wherein the another stencil has through patterns only corresponding to the soldering pads of the printed circuit board.

9 A method of mounting a first circuit component and a second circuit component on a surface of a printed circuit board, wherein the first circuit component has a plurality of solder bumps, the second circuit component has a plurality of solder pins, and the surface of the circuit component has first soldering pads corresponding to the plurality of solder bumps and second soldering pads corresponding to the plurality of solder pins of the second circuit component, the method comprising the steps of:
(a) overlaying a solder paste on the second soldering pads of the printed circuit board by means of a stencil, wherein the stencil has through patterns only corresponding to the second soldering pads of the printed circuit board;
(b) syringing a paste flux on the first soldering pads of the printed circuit board, wherein the paste flux does not contain solder balls or other types of solder;
(c) mounting the first and second circuit components on the first and second soldering pads of the printed circuit board, respectively; and
(d) reflowing the first and second circuit components on the first and second soldering pads of the printed circuit board.

10. An electronic device, comprising a circuit component mounted a surface of a printed circuit board, wherein the circuit component has a plurality of solder bumps, and the surface of the circuit component has soldering pads corresponding to the plurality of solder bumps, the circuit component being mounted on the surface of the printed circuit board by the method comprising the steps of:
(a) overlaying said paste flux on the soldering pads of the printed circuit board, wherein said paste flux does not contain solder balls or other types of solder;
(b) mounting the circuit component on the soldering pads of the printed circuit board; and
(c) reflowing the circuit component on the soldering pads of the printed circuit board.

11. The method according to claim 10, wherein step (a) is conducted by spreading the paste flux by means of a squeegee.

12 The method according to claim 10, wherein step (a) is conducted by syringing the paste flux by means of a glue gun.

13 The method according to claim 11, wherein the thickness of the paste flux spread on the surface of the printed circuit board does not exceed 0.3 mm.

14. The method according to claim 11, wherein the length of the surface area of the paste flux spread on the surface of the printed circuit board does not exceed 3 mm and the width thereof does not exceed 3 mm.

15. The method according to claim 12, wherein the height of the paste flux syringed on the surface of the printed circuit board does not exceed 3 mm, the length thereof does not exceed 3 mm, and the width thereof does not exceed 3 mm.

16. An electronic device, comprising a first circuit component and a second circuit component mounted on a surface of a printed circuit board, wherein the first circuit component has a plurality of solder bumps, the second circuit component has a plurality of solder pins, and the surface of the circuit component has first soldering pads corresponding to the plurality of solder bumps and second soldering pads corresponding to the plurality of solder pins of the second circuit component, the first and second circuit components being mounted on the surface of the printed circuit board by the method comprising the steps of:
(a) overlaying a paste flux on the first soldering pads of the printed circuit board, wherein said paste flux does not contain solder balls or other types of solder;
(b) overlaying a solder paste on the second soldering pads of the printed circuit board by means of a stencil, wherein the surface of the stencil facing the printed circuit board has semi-etched openings corresponding to the first soldering pads of the printed circuit board, and the stencil has through patterns only corresponding to the second soldering pads of the printed circuit board;
(c) mounting the first and second circuit components on the first and second soldering pads of the printed circuit board, respectively; and
(d) reflowing the first and second circuit components on the first and second soldering pads of the printed circuit board.

17. The electronic device according to claim 6, wherein step (a) is conducted by spreading the paste flux on another stencil positioned on the printed circuit board by means of a squeegee, and wherein the another stencil has through patterns only corresponding to the soldering pads of the printed circuit board.

18. An electronic device, comprising a first circuit component and a second circuit component mounted on a surface of a printed circuit board, wherein the first circuit component has a plurality of solder bumps, the second circuit component has a plurality of solder pins, and the surface of the circuit component has first soldering pads corresponding to the plurality of solder bumps and second soldering pads corresponding to the plurality of solder pins of the second circuit component, the first and second circuit components being mounted on the surface of the printed circuit board by the method comprising the steps of:
(a) overlaying a solder paste on the second soldering pads of the printed circuit board by means of a stencil, wherein the stencil has through patterns only corresponding to the second soldering pads of the printed circuit board;
(b) syringing a paste flux on the first soldering pads of the printed circuit board, wherein the paste flux does not contain solder balls or other types of solder;
(c) mounting the first and second circuit components on the first and second soldering pads of the printed circuit board, respectively; and
(d) reflowing the first and second circuit components on the first and second soldering pads of the printed circuit board.
